(19) United States
(12) Patent Application Publication
(10) Pub. No.: US 2012/0247827 A1
(43) Pub. Date: Oct. 4, 2012

(54) Protective eyeglass magnetic sleeve for cell phone radiation

(76) Inventor: Pablo P. Gonzalez, Riverside, CA (US)

(21) Appl. No.: 13/066,005

(22) Filed: Apr. 4, 2011

(51) Int. Cl. H05K 9/00

(52) U.S. Cl. 174/391

(57) ABSTRACT

The Protective Eyeglass Magnetic Sleeve for Cell Phone Radiation, provides a lightweight malleable rubber sheath worn over the arm of eyeglasses or sunglasses. It may also be applied directly to the telephone receiver itself or blue tooth devices. The sleeve is embedded with a series of small circular magnets measuring approximately five-sixteenths ( 5/16) of an inch. The magnets are strategically placed in the sleeve and alternately positioned positive to negative (+−), thereby generating a magnetic field designed to block the harmful electromagnetic waves emitted by cell phones, without compromising the quality of the voice signal being emitted.

### FIELD OF THE INVENTION

The present invention pertains to the field of electromagnetic frequency shielding devices, and more specifically, to the field of cellular phone radiation shielding devices.

### BACKGROUND OF THE INVENTION

The prior art has put forth the following designs for cellular phone shielding devices:

U.S. Pat. No. 6,097,340 to Daniel Chang describes an antenna having a core which holds a winding assembly on the inside for receiving and transmitting a radio signal, and a resin shell molded on the core, wherein a metal shield is embedded in the resin shell and covered on one half of the periphery of the core to limit the direction of radiation of the radio frequency energy from the winding assembly, and to prevent the radiation from hurting the user's brain.

U.S. Pat. No. 6,404,403 to Kim R. Kunz and Frederick J. Wood describes a Radio Frequency Radiation Shield Unit for a wireless telephone for protecting the user from radio frequency radiation. It has a housing with an open bottom end that allows it to be slid over the top end of the wireless telephone. The housing also has an aperture in its top end that allows the antenna of the phone to extend upwardly and outwardly there from. An antenna shield member extends upwardly from the top end of the housing and it is positioned between the antenna and the head of the person using the telephone to protect the person from radiation emitted by the antenna. In one presently preferred embodiment, the Radio Frequency Radiation Shield Unit is fabricated of a plastic material having carbon fibers embedded therein for absorbing and dispersing radio frequency radiation.

U.S. Pat. No. 6,897,826 to Kim R. Kunz describes a radio frequency radiation shield unit that is removable mounted on the antenna of a wireless telephone. It has an upright oriented front wall member that is detachably connected to an upright oriented rear wall member. These wall members are fabricated of a plastic material having carbon fibers therein for absorbing and dispersing radiation. A chamber is formed between the front wall member and rear wall member and one or more membranes are positioned therein and these membranes are made of carbon fiber material that has been cut into strips and tightly woven together. A tubular collar is formed on the rear surface of the lower portion of the rear wall member.

None of these prior art references describe the present invention.

### SUMMARY OF THE INVENTION

It is an object of the present invention to provide a device for the purpose of the invention is to protect the consumer from cancer causing radiation waves emitted by cell phones, specifically, through the use of a protective magnetic sleeve strategically placed on glasses and blue tooth devices.

### BRIEF DESCRIPTION OF THE DRAWINGS

FIG. 1 is a close-up perspective view of the device of the present invention.

FIG. 2 is an elevational view of the device of the present invention.

FIG. 3 is a second elevational view of device of the present invention.

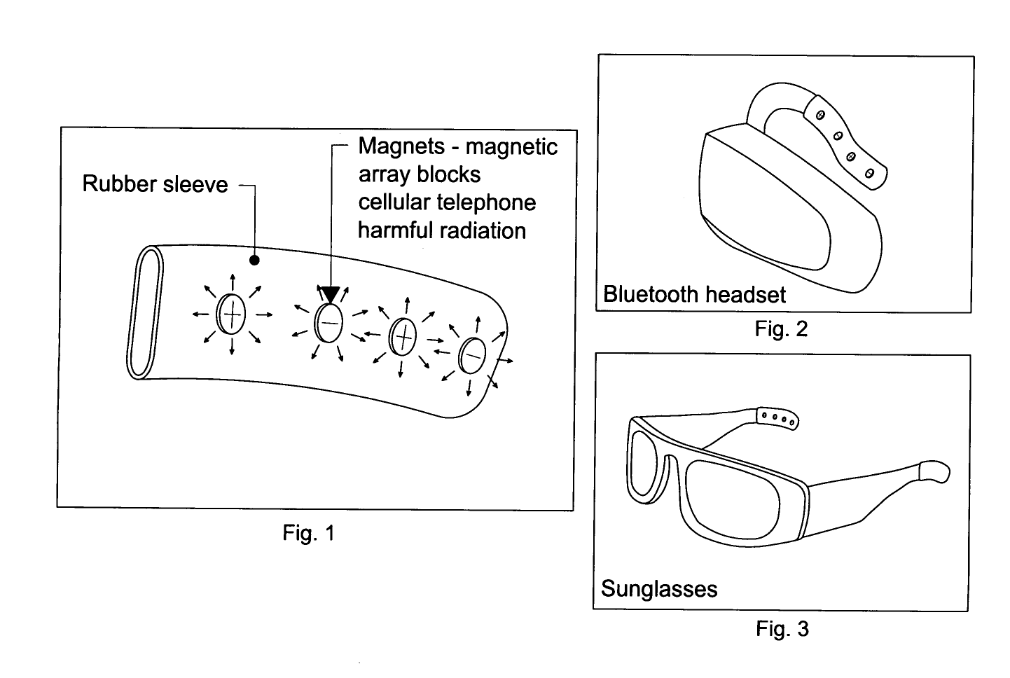

### DETAILED DESCRIPTION OF THE INVENTION

### Background

One the most explosive new technologies to come out of the last twenty years is the cellular telephone. In fact, it is estimated that worldwide use of cellular telephones reached 4 billion people by year end 2009. The basic concept of cellular phones began in 1947, when AT& T researchers sought ways to increase the traffic capacity and frequency of mobile communication in police car radios. However, nonexistent technology and stringent FCC regulations postponed availability until 1982, when the FCC authorized commercial cellular use. As a result of this regulation, the scientific advances of the intervening years and increased competition among communications companies put the cellular telephone on the fast track. Today's widespread use of these revolutionary devices is unsurprising, since they now offer a virtually endless array of benefits. In addition to serving as a practical means of communication while on the go, technological advances have evolved cell phones into mini computers capable of providing wireless Internet access, email, texting, tweeter messages and GPS technology. In fact, cellular and digital telephones have become indispensable to millions the world over.

### Product Need

Since the development and marketing of the cell phone, the scientific community has labeled reports associating the electromagnetic waves of cell phones with serious health concerns, including brain tumors, as “inconclusive”.

The clinical horizon of medical opinion changed with a definitive report published on Aug. 25, 2009, titled Cellphones and Brain Tumors, 15 Reasons for Concern. The foundational research for the report was the effort of 13 countries. Page 13 of the referenced report sets forth the most disturbing findings, including the fact that:

1. “For every 100 hours of cell phone use, the risk of cancer increases by 5%.

2. For every year of cell phone use, the risk of brain cancer increases by 8%.

3. After 10 years of more of digital phone use, there was a 280% increased risk of brain cancer. And most disturbing of all,

4. For digital cell phone user who were teenagers or younger when they first started using a cell phone, there was a 420% increased risk of brain cancer.”

In light of the foregoing findings, in January of 2010, the State of Maine introduced emergency legislation that would require warning of the dangers associated with cell phone use. The City of San Francisco is also introducing similar legislation.

### How it Works:

The present invention, hereinafter referred to as the Protective Eyeglass Magnetic Sleeve for Cell Phone Radiation, is a lightweight malleable rubber sheath worn over the arm of eyeglasses or sunglasses. It may also be applied directly to the telephone receiver itself or blue tooth devices. The sleeve is embedded with a series of small circular magnets measuring approximately five-sixteenths ( 5/16) of an inch. The magnets are strategically placed in the sleeve and alternately positioned positive to negative (+−), thereby generating a magnetic'field designed to block the harmful electromagnetic waves emitted by cell phones, without compromising the quality of the voice signal being emitted. Specifically, the electromagnetic properties of a magnet are generally understood and seen as the force that cause magnets to attract or repel each other. It is this repelling or attracting force, also known as magnetic forces, that the devise ultimately uses to neutralize and repel the electromagnetic cancer causing cell phone signal.

The principles behind the invention are summarized as follows:

The positive and negative polarity of the embedded magnets are arranged in specific and predetermined sequential order (−+) manipulating the electromagnetic force in order to create a magnetic shield.

The inherent electromagnetic properties of the cancer causing cell phone signal are then confronted, neutralized and repelled by this electromagnetic shield which, again, is generated by the magnets.

It should be noted that the harnessing of electromagnetic forces is neither new nor novel to this invention. In fact, the power of electromagnetic shield forces has been used in amusement park rides breaks to stop objects of massive weight traveling at great speeds.

Extremely compact and lightweight in design, the Protective Eyeglass Magnetic Sleeve for Cell Phone Radiation is a rectangular shaped sheath with soft rounded edges and feels gentle against the skin, making them virtually undetectable during wear. As such, the sheath is produced in a variety of sizes and styles to accommodate personal needs. Open on one end, this sheath easily slides over the end of an earpiece on a pair of sunglasses or eyeglasses, or as mentioned, directly over a personal headset or telephone receiver. Easily applied, these lightweight sheathes are effortlessly adhered and removed in a matter of seconds.

### CONCLUSION

The Protective Eyeglass Magnetic Sleeve for Cell Phone Radiation is a truly innovative product invention which offers consumers a number of significant benefits and advantages.

The Protective Eyeglass Magnetic Sleeve for Cell Phone is safe and effective while being simple and easy to use. First and foremost, the sheath provides an effective shield to the cancer causing electromagnetic frequencies emitted by cellular devices. Second, it is easily applied and comfortable to use—these flexible sheathes prove an invaluable and practical health commodity.

Although the invention has been described with respect to specific embodiments, it is so described by way of presentation and not limitation. Various modifications may in fact become apparent to the person of ordinary skill in the art consistent with the spirit and scope of the invention as described here in text and drawings and in conjunction with the appended claims.

1. A device for protecting a user from cell phone radiation comprising a lightweight malleable rubber sheath worn over the arm of eyeglasses or sunglasses wherein the sheath is embedded with a multiplicity of circular magnets, wherein the circular magnets measure approximately five-sixteenths ( 5/16) of an inch in diameter, and wherein the magnets are placed in the sheath alternating the position of the positive and negative (+−) poles of the magnet, thereby generating a magnetic field designed to block the harmful electromagnetic waves emitted by cell phones, without compromising the quality of the voice signal being emitted.

2. A lightweight malleable rubber sheath applied directly to a telephone receiver or blue tooth devices wherein the sheath is embedded with a multiplicity of circular magnets, wherein the circular magnets measure approximately five-sixteenths ( 5/16) of an inch in diameter, and wherein the magnets are placed in the sheath alternating the position of the positive and negative (+−) poles of the magnet, thereby generating a magnetic field designed to block the harmful electromagnetic waves emitted by cell phones, without compromising the quality of the voice signal being emitted.

3. The device of claim 1 wherein the device is essentially rectangular in shape having rounded edges and is comprised of material which feels soft against the skin.

4. The device of claim 2 wherein the device is essentially rectangular in shape having rounded edges and is comprised of material which feels soft against the skin.

5. The device of claim 3 wherein the device is configured to fit over the arm of a pair of eyeglasses.

6. The device of claim 4 wherein the device is configured to fit over a Bluetooth device.
